(19) United States
(12) Patent Application Publication
(10) Pub. No.: US 2026/0301831 A1
(43) Pub. Date: Oct. 1, 2026

(54) MEMORY DEVICE AND OPERATING METHOD OF THE MEMORY DEVICE

(71) Applicant: SK hynix Inc., Icheon-si Gyeonggi-do (KR)

(72) Inventor: Won Hee LEE, Icheon-si Gyeonggi-do (KR)

(73) Assignee: SK hynix Inc., Icheon-si Gyeonggi-do (KR)

(21) Appl. No.: 19/383,358

(22) Filed: Nov. 7, 2025

(30) Foreign Application Priority Data
Mar. 31, 2025 (KR) 10-2025-0041158

(51) Int. Cl. G11C 16/34; G11C 16/08; G11C 16/10

(52) U.S. Cl. CPC G11C 16/3459; G11C 16/08; G11C 16/102

(57) ABSTRACT

The present disclosure relates to a memory device and an operating of the memory device. The memory device includes a memory block including a plurality of cell strings, a peripheral circuit configured to perform a program operation on the memory block. A control logic configured to control the peripheral circuit to perform the program operation, in which the control logic sets a detailed operation of each of a plurality of program loops included in the program operation such that a program verify operation of each of the plurality of program loops is performed only for at least one selected cell string of the plurality of cell strings.

### CROSS-REFERENCE TO RELATED APPLICATION

The present application claims priority under 35 U.S.C. § 119(a) to Korean patent application number 10-2025-0041158 filed on Mar. 31, 2025 in the Korean Intellectual Property Office, the entire contents of which application is incorporated herein by reference.

### BACKGROUND

### 1. Technical Field

Various embodiments of the present disclosure generally relate to an electronic device, and more particularly, to an electronic device including a memory device and an operating method of the memory device.

### 2. Related Art

A storage device stores data. The storage device includes a memory device in which data is stored and a memory controller that controls the memory device. The memory device is implemented using a semiconductor such as silicon (Si), germanium (Ge), gallium arsenide (GaAs), indium phosphide (InP), and the like. Memory devices are categorized into volatile memory devices and non-volatile memory devices.

Volatile memory devices lose their stored data when the power supply is cut off. Examples of the volatile memory devices include SRAM (Static RAM), DRAM (Dynamic RAM), SDRAM (Synchronous DRAM), etc.

Non-volatile memory devices retain data even when the power supply is cut off. Examples of the non-volatile memory devices include Read Only Memory (ROM), Programmable Read Only Memory (PROM), Electrically Programmable Read Only Memory (EPROM), Electrically Erasable and Programmable Read Only Memory (EEPROM), flash memory, Phase-change Random Access Memory (PRAM), Magnetic Random Access Memory (MRAM), Resistive Random Access Memory (RRAM), Ferroelectric Random Access Memory (FRAM), etc. Flash memory is categorized into two types: NOR and NAND.

A memory device includes a plurality of memory cells capable of storing data, and may perform a program operation to store data in the plurality of memory cells. The program operation may include a plurality of program loops, and the plurality of program loops may include a program pulse apply operation and a program verify operation.

### SUMMARY

According to an embodiment, a memory device may include a memory block including a plurality of cell strings, a peripheral circuit configured to perform a program operation on the memory block, and control logic configured to control the peripheral circuit to perform the program operation, wherein the control logic sets a detailed operation of each of a plurality of program loops included in the program operation such that a program verify operation of each of the plurality of program loops is performed only for at least one selected cell string of the plurality of cell strings.

According to an embodiment, a memory device may include a memory block including a plurality of cell strings, a peripheral circuit configured to sequentially select a plurality of pages corresponding to a plurality of word lines coupled to the memory block, and performing a program operation on each of the plurality of pages, and control logic configured to control the peripheral circuit to perform the program operation, wherein the control logic sets a detailed operation for each of a plurality of program loops included in the program operation such that the plurality of program loops include a program verify operation in the program operation for at least one page of the plurality of pages, and the plurality of program loops omit the program verify operation in the program operation for remaining pages of the plurality of pages except for the at least one page.

According to an embodiment, a method of operating a memory device may include performing a program pulse apply operation by applying a program voltage to a selected word line from a plurality of word lines coupled to a memory block, the memory block including a plurality of cell strings, performing a program verify operation for a memory cell included in at least one cell string of the plurality of cell strings by sensing a current or a voltage through a bit line coupled to the at least one cell string, and omitting the program verify operation for remaining cell strings of the plurality of cell strings except for the at least one cell string, and performing a subsequent program operation by performing a subsequent program loop or selecting a subsequent word line from the plurality of word lines, based on a result of the program verify operation for the memory cell included in the at least one cell string.

### BRIEF DESCRIPTION OF THE DRAWINGS

FIG. 1 is a block diagram illustrating a storage device according to an embodiment of the present disclosure;

FIG. 2 is a diagram illustrating a memory device according to an embodiment of the present disclosure;

FIG. 3 is a diagram illustrating an embodiment of a memory cell array of FIG. 2;

FIG. 4 is a schematic diagram illustrating one memory block from a plurality of memory blocks shown in FIG. 3;

FIG. 5 is a schematic diagram illustrating an embodiment of another memory block from the plurality of memory blocks shown in FIG. 3;

FIGS. 6A, 6B, and 6C are diagrams illustrating embodiments of program operations of a memory device;

FIG. 7 is a diagram illustrating a plurality of program loops included in a program operation of a memory device;

FIG. 8 is a diagram illustrating a program pulse apply operation and a program verify operation;

FIG. 9 is a diagram illustrating a program operation according to an embodiment of the present disclosure;

FIG. 10 is a diagram illustrating a program operation according to an embodiment of the present disclosure;

FIG. 11 is a diagram illustrating a program operation according to an embodiment of the present disclosure;

FIG. 12 is a diagram illustrating a program operation according to an embodiment of the present disclosure;

FIG. 13 is a block diagram illustrating a storage device including a memory device according to an embodiment of the present disclosure;

FIG. 14 is a block diagram illustrating an example application of the storage device of FIG. 13; and

FIG. 15 is a block diagram illustrating a computing system including the storage device described with reference to FIG. 14.

### DETAILED DESCRIPTION

Specific structural or functional descriptions of examples of embodiments in accordance with concepts which are disclosed in this specification are illustrated only to describe the examples of embodiments in accordance with the concepts and the examples of embodiments in accordance with the concepts may be carried out by various forms but the descriptions are not limited to the examples of embodiments described in this specification.

Hereinafter, embodiments of the present disclosure will be described in detail with reference to the accompanying drawings in order for those skilled in the art to be able to readily implement the technical spirit of the present disclosure.

An embodiment of the present disclosure provides a memory device having improved program performance and an operating method of the memory device.

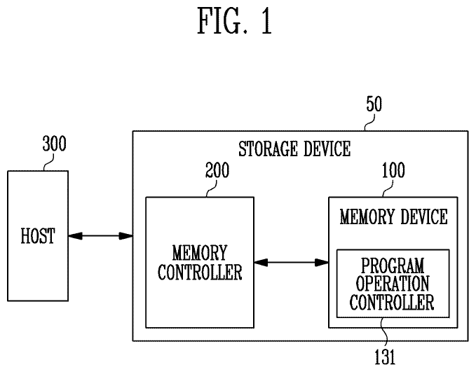

FIG. 1 is a block diagram illustrating a storage device 50 according to an embodiment of the present disclosure.

Referring to FIG. 1, the storage device 50 may include a memory device 100 and a memory controller 200 which controls the operation of the memory device 100.

The storage device 50 may store data under control of a host 300, and examples of the storage device 50 may be a cellular phone, a smartphone, an MP3 player, a laptop computer, a desktop computer, a gaming machine, a television, a tablet PC, and an in-vehicle infotainment system etc.

The storage device 50 may be manufactured as one of various types of storage devices depending on a host interface, which is a method of communication with the host 300. For example, the storage device 50 may be a multimedia card in the form of SSD, MMC, eMMC, RS-MMC, or micro-MMC, a secure digital card in the form of SD, mini-SD, or micro-SD, a universal serial bus (USB) storage device, a universal flash storage (UFS) device, a storage device in the form of a personal computer memory card international association (PCMCIA) card, a storage device in the form of a peripheral component interconnection (PCI) card, a storage device in the form of a PCI express (PCI-E) card, a storage device in the form of a compact flash (CF) card, a smart media card, a memory sticks, or the like.

The storage device 50 may be manufactured in one of various kinds of package forms. For example, the storage device 50 may be manufactured in one of various types of package forms, such as package on package (POP), system in package (SIP), system on chip (SOC), multi-chip package (MCP), chip on board (COB), wafer-level fabricated package (WFP), wafer-level stack package (WSP), and the like.

The memory device 100 may store data. The memory device 100 may operate in response to control of the memory controller 200. The memory device 100 may include a memory cell array including a plurality of memory cells which store data.

The memory cells may each include a single level cell (SLC) that stores one data bit, a multi-level cell (MLC) that stores two data bits, a triple level cell (TLC) that stores three data bits, or a quad level cell (QLC) which stores four data bits.

The memory cell array may include a plurality of memory blocks. Each memory block may include a plurality of memory cells. A single memory block may include a plurality of pages. In an embodiment, a page may be a unit for storing data in the memory device 100 or reading data stored in the memory device 100. A memory block may be a unit for erasing data.

In an embodiment, the memory device 100 may include Double Data Rate Synchronous Dynamic Random Access Memory (DDR SDRAM), Low Power Double Data Rate 4 (LPDDR4) SDRAM, Graphics Double Data Rate (GDDR) SDRAM, Low Power Double Data Rate (LPDDR), Rambus Dynamic Random Access Memory (RDRAM), NAND flash memory, Vertical NAND flash memory, NOR flash memory, resistive random access memory (RRAM), phase-change memory (PRAM), magneto resistive random access memory (MRAM), ferroelectric random access memory (FRAM), spin transfer torque random access memory (STT-RAM), and the like. For ease of description, it is assumed that the memory device 100 is a NAND flash memory.

The memory device 100 may receive a command and an address from the memory controller 200. The memory device 100 accesses a region selected by the received address in the memory cell array. When the memory device 100 accesses the selected region, it means that the memory device 100 performs an operation corresponding to the received command on the selected region. For example, the memory device 100 may perform a write operation (a program operation), a read operation, and an erase operation. During a program operation, the memory device 100 may program data into the region selected by the address. During a read operation, the memory device 100 may read data from the region selected by the address. During an erase operation, the memory device 100 may erase data stored in the region selected by the address.

According to embodiments, the memory device 100 may include a program operation controller 131. The memory device 100 may perform a program operation to store data in memory cells included in the memory device 100 in response to a program command received from the memory controller 200. The program operation may include a program loop. The program loop may include a program pulse apply operation to apply a program voltage and a program verify operation to verify a program result using a verify voltage. The program operation may be performed to increase a threshold voltage of a memory cell. The program operation may be performed by repeating a plurality of program loops PL. One program loop may include a program pulse apply operation to apply a program pulse and a program verify operation to verify a program result using a verify voltage.

In an embodiment, for improved program performance, during a program operation for a selected memory block, the program operation controller 131 may control a program loop such that a program pulse apply operation and a program verify operation may be performed for memory cells included in at least one selected cell string of a plurality of cell strings included in the selected memory block, and only the program pulse apply operation may be performed for memory cells included in the remaining cell strings. In other words, the program loop may be controlled such that a program verify operation may be skipped for the memory cells included in the remaining cell strings.

Furthermore, during the program operation for the selected memory block, the program operation controller 131 may control the program loop such that the program pulse apply operation and the program verify operation may be performed for memory cells coupled to at least one word line defined as a weak word line based on the position thereof among a plurality of word lines coupled to the selected memory block, and only the program pulse apply operation may be performed for memory cells included in the remaining word lines. In other words, the program loop may be controlled such that a program verify operation may be skipped for the memory cells included in the remaining word lines.

In an embodiment, when the program operation controller 131 programs the memory cells included in the selected memory block in a single-level cell programming scheme which stores one data bit per cell, the program operation controller 131 may control the program loop to perform the program pulse apply operation and the program verify operation only for the memory cells included in the selected cell string or the memory cells coupled to the selected word line, and to skip the program verify operation for the memory cells included in the remaining cell strings or the memory cells coupled to the remaining word lines, thereby improving a program operation speed and current consumption during the program operation.

Details of skipping a program verify operation during a program operation in a memory device and an operating method thereof according to embodiments of the present disclosure will be described below with reference to the following drawings.

The memory controller 200 controls the overall operation of the storage device 50.

When power is applied to the storage device 50, the memory controller 200 may execute firmware FW. The firmware FW may include a Host Interface Layer HIL which receives input requests from the host 300 or outputs responses to the host 300, a Flash Translation Layer FTL which manages operations between an interface of the host 300 and an interface of the memory device 100, and a Flash Interface Layer FIL which provides commands to the memory device 100 or receives responses from the memory device 100.

In an embodiment, the memory controller 200 may receive data and a logical address LA from the host 300, and may convert the logical address LA into a physical address PA which indicates an address of memory cells in the memory device 100 where the data included in the memory device 100 is to be stored. The logical address LA may be a Logical Block Address LBA, and the physical address PA may be a Physical Block Address PBA.

The memory controller 200 may control the memory device 100 to perform a program operation, a read operation, or an erase operation in response to a request from the host 300. During a program operation, the memory controller 200 may provide a program command, a physical block address, and data to the memory device 100. During a read operation, the memory controller 200 may provide a read command and a physical block address to the memory device 100. During an erase operation, the memory controller 200 may provide an erase command and a physical block address to the memory device 100.

In an embodiment, the memory controller 200 may control the memory device 100 to perform a program operation, a read operation, or an erase operation, independent of a request from the host 300. For example, the memory controller 200 may control the memory device 100 to perform a program operation, a read operation, or an erase operation which is performed for background operations such as wear leveling, garbage collection, read reclaim, and the like.

The host 300 may communicate with the storage device 50 by using at least one of the following communication methods: Universal Serial Bus (USB), Serial AT Attachment (SATA), Serial Attached SCSI (SAS), High Speed Interchip (HSIC), Small Computer System Interface (SCSI), Peripheral Component Interconnection (PCI), PCI Express (PCIe), NonVolatile Memory Express (NVMe), Universal Flash Storage (UFS), Secure Digital (SD), MultiMedia Card (MMC), Embedded MultiMedia Card (eMMC), Dual In-line Memory Module (DIMM), Registered DIMM (RDIMM), Load Reduced DIMM (LRDIMM), and the like.

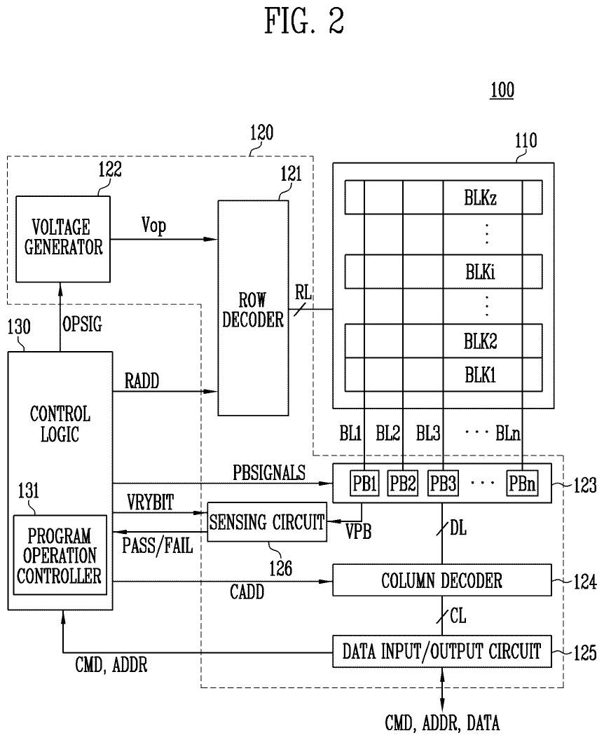

FIG. 2 is a diagram illustrating the memory device according to an embodiment of the present disclosure.

Referring to FIG. 2, the memory device 100 may include a memory cell array 110, a peripheral circuit 120, and control logic 130.

The memory cell array 110 includes a plurality of memory blocks BLK1 to BLKz. The plurality of memory blocks BLK1 to BLKz are coupled to a row decoder 121 via row lines RL. The plurality of memory blocks BLK1 to BLKz may be coupled to a page buffer group 123 via bit lines BL1 to BLn. Each of the plurality of memory blocks BLK1 to BLKz includes a plurality of memory cells. In an embodiment, the plurality of memory cells are non-volatile memory cells. Memory cells coupled to the same word line may be defined as one page. In other words, the memory cell array 110 includes a plurality of physical pages. Thus, a single memory block may include a plurality of pages.

The memory cells included in the memory cell array 110 may be configured a Single Level Cell (SLC), which stores one data bit, a Multi Level Cell (MLC), which stores two data bits, a Triple Level Cell (TLC), which stores three data bits, or a Quad Level Cell (QLC), which stores four data bits.

The peripheral circuit 120 may perform a program operation, a read operation, or an erase operation to a selected region of the memory cell array 110 under control of the control logic 130. The peripheral circuit 120 may drive the memory cell array 110. For example, the peripheral circuit 120 may program a selected memory block of the plurality of memory blocks BLK1 to BLKz included in the memory cell array 110 in a single-level cell programming scheme. Single-level cell (SLC) programming is a programming scheme by which each memory cell included in the selected memory block is programmed to have either an erase state or a program state, i.e., each memory cell stores one data bit.

The peripheral circuit 120 may apply various operation voltages to the row lines RL and the first to nth bit lines BL1 to BLn under the control of the control logic 130, or may discharge the applied voltages.

The peripheral circuit 120 may include the row decoder 121, a voltage generator 122, the page buffer group 123, a column decoder 124, a data input/output circuit 125, and a sensing circuit 126.

The peripheral circuit 120 drives the memory cell array 110. For example, the peripheral circuit 120 may drive the memory cell array 110 to perform a program operation, a read operation, and an erase operation.

The row decoder 121 is coupled to the memory cell array 110 via the row lines RL. The row lines RL may include one or more source select lines, a plurality of word lines, and one or more drain select lines. In an embodiment, the word lines may include normal word lines and dummy word lines. The row lines RL may further include a pipe select line.

The row decoder 121 operates in response to control from the control logic 130. The row decoder 121 receives a row address RADD from the control logic 130.

The row decoder 121 decodes the row address RADD. The row decoder 121 selects at least one memory block of the memory blocks BLK1 to BLKz based on the decoded address. Further, the row decoder 121 may select at least one word line of the selected memory block to apply voltages generated by the voltage generator 122 to at least one word line WL based on the decoded address.

For example, during a program operation, the row decoder 121 may apply a program voltage to a selected word line and apply a program pass voltage at a level lower than the program voltage to unselected word lines. During a program verify operation, the row decoder 121 may apply a verify voltage to the selected word line and a verify pass voltage at a level higher than the verify voltage to the unselected word lines. During a read operation, the row decoder 121 may apply a read voltage to the selected word line and a read pass voltage at a level higher than the read voltage to the unselected word lines.

In an embodiment, an erase operation of the memory device 100 is performed in units of memory blocks. During the erase operation, the row decoder 121 may select one memory block according to the decoded address. During the erase operation, the row decoder 121 may apply a ground voltage to the word lines coupled to the selected memory block.

The voltage generator 122 operates in response to control from the control logic 130. The voltage generator 122 generate a plurality of voltages using an external power supply voltage supplied to the memory device. Specifically, the voltage generator 122 may generate various operation voltages Vop for program, read, and erase operations in response to an operation signal OPSIG. For example, the voltage generator 122 may generate a program voltage, a verify voltage, a pass voltage, a read voltage, and an erase voltage in response to control of the control logic 130.

In an embodiment, the voltage generator 122 may regulate an external power supply voltage to generate an internal power supply voltage. The internal power supply voltage generated by the voltage generator 122 serves as the operation voltage of the memory device 100.

In an embodiment, the voltage generator 122 may generate a plurality of voltages using an external power supply voltage or an internal power supply voltage.

The generated operation voltages Vop may be supplied to the memory cell array 110 by the row decoder 121.

The page buffer group 123 includes first to nth page buffers PB1 to PBn. The first to nth page buffers PB1 to PBn are coupled to the memory cell array 110 via the first to nth bit lines BL1 to BLn, respectively. The first to nth page buffers PB1 to PBn are operated in response to control from the control logic 130. Specifically, the first to nth page buffers PB1 to PBn may operate in response to page buffer control signals PBSIGNALS. For example, the first to nth page buffers PB1 to PBn may store data received via the first to nth bit lines BL1 to BLn, or may sense voltages or currents of the first to nth bit lines BL1 to BLn during a read or verify operation.

Specifically, during a program operation, the first to nth page buffers PB1 to PBn may transfer data DATA received via the data input/output circuit 125 to selected memory cells via the first to nth bit lines BL1 to BLn when a program pulse is applied to the selected word line. Based on the received data DATA, the memory cells of the selected page are programmed. A memory cell coupled to a bit line to which a program enable voltage (e.g., a ground voltage) is applied will have an elevated threshold voltage. A threshold voltage of a memory cell coupled to a bit line to which a program inhibit voltage (e.g., a power supply voltage) is applied may be maintained. During a program verify operation, the first to nth page buffers PB1 to PBn read page data from the selected memory cells via the first to nth bit lines BL1 to BLn.

During a read operation, the first to nth page buffers PB1 to PBn read the data DATA from the memory cells of the selected page through the first to nth bit lines BL1 to BLn, and may output the read data DATA to the data input/output circuit 125 under control of the column decoder 124.

During an erase operation, the first to nth page buffers PB1 to PBn may float the first to nth bit lines BL1 to BLn.

The column decoder 124 may transfer data between the data input/output circuit 125 and the page buffer group 123 in response to a column address CADD. For example, the column decoder 124 may exchange data with the first to nth page buffers PB1 to PBn via data lines DL, or may exchange data with the data input/output circuit 125 via column lines CL.

The data input/output circuit 125 may transfer a command CMD and an address ADDR received from the memory controller 200 as described with reference to FIG. 1 to the control logic 130, or may exchange the data DATA with the column decoder 124.

The sensing circuit 126 may generate a reference current in response to an allowable bit signal VRYBIT in a read operation or a verify operation, and may output a pass signal PASS or a fail signal FAIL by comparing a sensing voltage VPB received from the page buffer group 123 and a reference voltage generated by the reference current.

The control logic 130 may control the peripheral circuit 120 by outputting the operation signal OPSIG, the row address RADD, the page buffer control signals PBSIGNALS, and the allowable bit signals VRYBIT in response to the command CMD and the address ADDR. In addition, the control logic 130 may respond to the pass or fail signal PASS or FAIL to determine whether the verify operation has passed or failed.

The control logic 130 may include the program operation controller 131. The program operation controller 131 may control the peripheral circuit 120 to set a program loop during a program operation of the selected memory block of the memory device 100 to perform a program pulse apply operation and a program verify operation for memory cells included in at least one of the selected cell strings of the plurality of cell strings included in the selected memory block and perform only a program pulse apply operation for memory cells included in the remaining cell strings, and to perform the program operation for the selected memory block in accordance with the set program loop. In other words, the peripheral circuit 120 may be controlled to skip the program verify operation for the memory cells included in the remaining cell strings except the selected cell string when the program operation is performed for the selected memory block.

Furthermore, the program operation controller 131 may control the peripheral circuit 120 to set a program loop during a program operation for the selected memory block to perform a program pulse apply operation and a program verify operation for memory cells coupled to at least one word line defined as a weak word line based on the position thereof among the plurality of word lines coupled to the selected memory block and perform only a program pulse apply operation for memory cells coupled to the remaining word lines, and to perform the program operation for the selected memory block according to the set program loop. In other words, the peripheral circuit 120 may be controlled to skip the program verify operation for the memory cells coupled to the remaining word lines except the word line defined as the weak word line during the program operation for the selected memory block.

Further, the program operation controller 131 may select a cell string for which a program verify operation is performed, based on the selected word line during the program operation. For example, the program operation controller 131 may allow the plurality of word lines to correspond to different cell strings, may selectively perform a program verify operation only for cell strings corresponding to the selected word line during a program operation, and may skip the program verify operation for the remaining cell strings. Further, when a program operation is performed by sequentially selecting the plurality of word lines, the program operation controller 131 may sequentially select at least one cell string for which the program verify operation is performed.

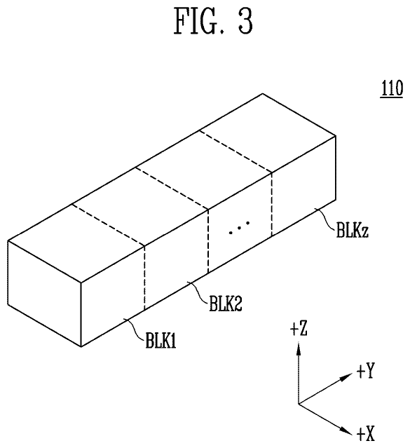

FIG. 3 is a diagram illustrating an embodiment of the memory cell array of FIG. 2.

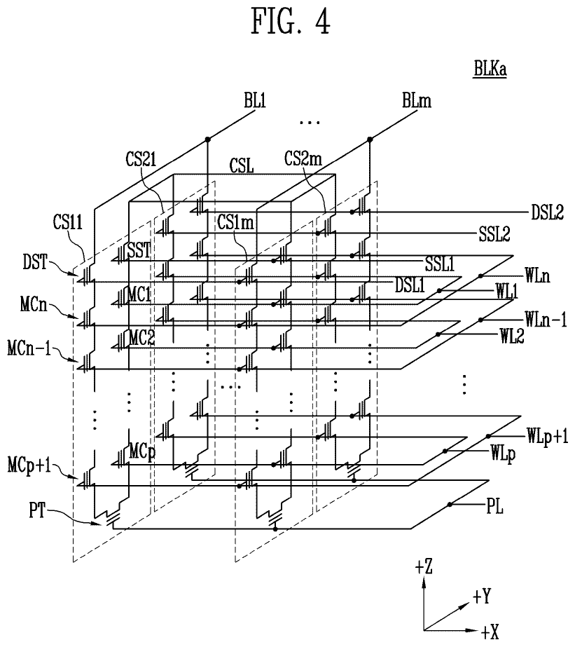

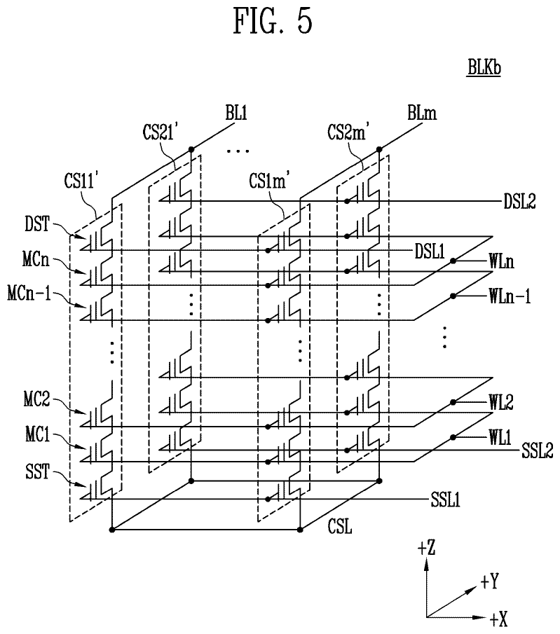

Referring to FIG. 3, the memory cell array 110 includes the plurality of memory blocks BLK1 to BLKz. Each memory block has a three-dimensional structure. Each memory block includes a plurality of memory cells stacked on a substrate. The plurality of memory cells are arranged along an +X direction, a +Y direction, and a +Z direction. The structure of each memory block will be described in more detail with reference to FIGS. 4 and 5.

FIG. 4 is a schematic illustrating one memory block from the memory blocks of FIG. 3.

Referring to FIG. 4, the memory block BLKa includes a plurality of cell strings CS11 to CS1m and CS21 to CS2m. In an embodiment, each of the plurality of cell strings CS11 to CS1m and CS21 to CS2m may be formed in a ‘U’ shape. Within the memory block BLKa, m cell strings are arranged in a row direction (i.e., the +X direction). In FIG. 5, two cell strings are shown to be arranged in a column direction (i.e., the +Y direction). However, this is for illustrative purposes only and it will be understood that three or more cell strings may be arranged in the column direction.

In an embodiment, one memory block may include a plurality of sub-blocks. One sub-block may include cell strings arranged in a “U” shape in one column.

Each of the plurality of cell strings CS11 to CS1m and CS21 to CS2m may include at least one source select transistor SST, first to nth memory cells MC1 to MCn, a pipe transistor PT, and at least one drain select transistor DST.

The source and drain select transistors SST and DST and the memory cells MC1 to MCn may have similar structures. In an embodiment, each of the source and drain select transistors SST and DST and the memory cells MC1 to MCn may include a channel layer, a tunneling insulation layer, a charge storage layer, and a blocking insulation layer. In an embodiment, a pillar for providing a channel layer may be provided in each cell string. In an embodiment, a pillar for providing at least one of the channel layer, the tunneling insulation layer, the charge storage layer, and the blocking insulation layer may be provided in each cell string.

The source select transistor SST of each cell string is coupled between a common source line CSL and memory cells MC1 to MCp.

In an embodiment, source select transistors of cell strings arranged in the same row are coupled to a source select line which extends in the row direction, and source select transistors of cell strings arranged in different rows are coupled to different source select lines. In FIG. 5, source select transistors of the cell strings CS11′ to CS1m′ in a first row are coupled to a first source select line SSL1. Source select transistors of the cell strings CS21′ to CS2m′ in a second row are coupled to a second source select line SSL2.

In an embodiment, the source select transistors of the cell strings CS11′ to CS1m′ and CS21′ to CS2m′ may be commonly coupled to a single source select line.

The first to nth memory cells MC1 to MCn of each cell string are coupled between the source select transistor SST and the drain select transistor DST.

The first to nth memory cells MC1 to MCn may be divided into first to pth memory cells MC1 to MCp and (p+1)th to nth memory cells MCp+1 to MCn. The first to pth memory cells MC1 to MCp are arranged sequentially in a reverse direction to the +Z direction, and are coupled in series between the source select transistor SST and the pipe transistor PT. The (p+1)th to nth memory cells MCp+1 to MCn are arranged sequentially in the +Z direction, and are coupled in series between the pipe transistor PT and the drain select transistor DST. The first to pth memory cells MC1 to MCp and the p+1th to nth memory cells MCp+1 to MCn are coupled through the pipe transistor PT. Gates of the first to nth memory cells MC1 to MCn of each cell string are coupled to first to nth word lines WL1 to WLn, respectively.

A gate of the pipe transistor PT of each cell string is coupled to a pipe line PL.

The drain select transistor DST of each cell string is coupled between the corresponding bit line and the memory cells MCp+1 to MCn. Cell strings arranged in the row direction are coupled to a drain select line which extends in the row direction. Drain select transistors of the cell strings CS11 to CS1m in the first row are coupled to a first drain select line DSL1. Drain select transistors of the cell strings CS21 to CS2m in the second row are coupled to a second drain select line DSL2.

Cell strings arranged in the column direction are coupled to a bit line which extends in the column direction. In FIG. 4, the cell strings CS11 and CS21 in a first column are coupled to the first bit line BL1. The cell strings CS1m and CS2m in an mth column are coupled to an mth bit line BLm.

Within cell strings arranged in the row direction, memory cells which are coupled to the same word line constitute one page. For example, the memory cells coupled to the first word line WL1 in the cell strings CS11 to CS1m in the first row constitute one page. The memory cells coupled to the first word line WL1 of the cell strings CS21 to CS2m of the second row constitute another page. By selecting one of the drain select lines DSL1 and DSL2, the cell strings arranged in one row direction may be selected. By selecting one of the word lines WL1 to WLn, one page of the selected cell strings may be selected.

In an embodiment, even-numbered bit lines and odd-numbered bit lines may be provided instead of first to mth bit lines BL1 to BLm. Even-numbered cell strings of the cell strings CS11 to CS1m or CS21 to CS2m arranged in the row direction may be coupled to the even-numbered bit lines, respectively, and odd-numbered cell strings of the cell strings CS11 to CS1m or CS21 to CS2m arranged in the row direction may be coupled to the odd-numbered bit lines, respectively.

In an embodiment, at least one of the first to nth memory cells MC1 to MCn may serve as a dummy memory cell. For example, one or more dummy memory cells may be provided to reduce the electric field between the source select transistor SST and the memory cells MC1 to MCp. Alternatively, for example, one or more dummy memory cells are provided to reduce the electric field between the drain select transistor DST and the memory cells MCp+1 to MCn. In an embodiment, as more dummy memory cells are provided, the operational reliability of the memory block BLKa is improved, while the size of the memory block BLKa increases. In an embodiment, as fewer memory cells are provided, the size of the memory block BLKa may decrease while the operational reliability of the memory block BLKa may decrease.

In an embodiment, to efficiently control one or more dummy memory cells, each of the dummy memory cells may have a required threshold voltage. Before or after an erase operation on the memory block BLKa, program operations on all or some of the dummy memory cells may be performed. When an erase operation is performed after the program operations are performed, the threshold voltages of the dummy memory cells may be controlled by controlling voltages applied to the dummy word lines coupled to each of the dummy memory cells, so that the dummy memory cells may have required threshold voltages.

FIG. 5 is a schematic illustrating an embodiment of one memory block from the plurality of memory blocks of FIG. 3.

Referring to FIG. 5, the memory block BLKb includes a plurality of cell strings CS11′ to CS1m′ and CS21′ to CS2m′. Each of the plurality of cell strings CS11′ to CS1m′ and CS21′ to CS2m′ extends along the +Z direction. Each of the plurality of cell strings CS11′ to CS1m′ and CS21′ to CS2m′ includes at least one source select transistor SST, the first to nth memory cells MC1 to MCn, and at least one drain select transistor DST which are stacked on a substrate (not shown) under a memory block BLKb.

In an embodiment, one memory block may include a plurality of sub-blocks. One sub-block may include cell strings arranged in an “I” shape in one column.

The source select transistor SST of each cell string is coupled between the common source line CSL and the memory cells MC1 to MCn. Source select transistors of cell strings arranged in the same row are coupled to the same source select line. Source select transistors of the cell strings CS11′ to CS1m′ arranged in the first row are coupled to the first source select line SSL1. Source select transistors of the cell strings CS21′ to CS2m′ arranged in the second row are coupled to the second source select line SSL2. In an embodiment, the source select transistors of the cell strings CS11′ to CS1m′, CS21′ to CS2m′ may be commonly coupled to one source select line.

The first to nth memory cells MC1 to MCn of each cell string are coupled in series between the source select transistor SST and the drain select transistor DST. Gates of the first to nth memory cells MC1 to MCn are coupled to the first to nth word lines WL1 to WLn, respectively.

The drain select transistor DST of each cell string is coupled between the corresponding bit line and the memory cells MC1 to MCn. Drain select transistors of cell strings arranged in the row direction are coupled to a drain select line extending in the row direction. Drain select transistors of the cell strings CS11′ to CS1m′ in the first row are coupled to the first drain select line DSL1. Drain select transistors of the cell strings CS21′ to CS2m′ in the second row are coupled to the second drain select line DSL2.

As a result, the memory block BLKb of FIG. 5 has an equivalent circuit similar to the memory block BLKa of FIG. 4, except that the pipe transistor PT is removed from each cell string.

In an embodiment, even-numbered bit lines and odd-numbered bit lines may be provided instead of the first to mth bit lines BL1 to BLm. Even-numbered cell strings of the cell strings CS11′ to CS1m′ or CS21′ to CS2m′ arranged in the row direction may be coupled to the even-numbered bit lines, respectively, and odd-numbered cell strings of the cell strings CS11′ to CS1m′ or CS21′ to CS2m′ arranged in the row direction may be coupled to the odd-numbered bit lines, respectively.

In an embodiment, at least one of the first to nth memory cells MC1 to MCn may serve as a dummy memory cell. For example, one or more dummy memory cells may be provided to reduce the electric field between the source select transistor SST and the memory cells MC1 to MCn. Alternatively, in an embodiment, one or more dummy memory cells are provided to reduce the electric field between the drain select transistor DST and the memory cells MC1 to MCn. In an embodiment, as more dummy memory cells are provided, the operational reliability of the memory block BLKb is improved, while the size of the memory block BLKb increases. In an embodiment, as fewer memory cells are provided, the size of the memory block BLKb may decrease while the operational reliability of the memory block BLKb may decrease.

In an embodiment, to efficiently control one or more dummy memory cells, each of the dummy memory cells may have a required threshold voltage. Before or after the erase operation on the memory block BLKb, program operations on all or some of the dummy memory cells may be performed. When the erase operation is performed after the program operations are performed, the dummy memory cells may have required threshold voltages by controlling voltages applied to the dummy word lines coupled to each of the dummy memory cells.

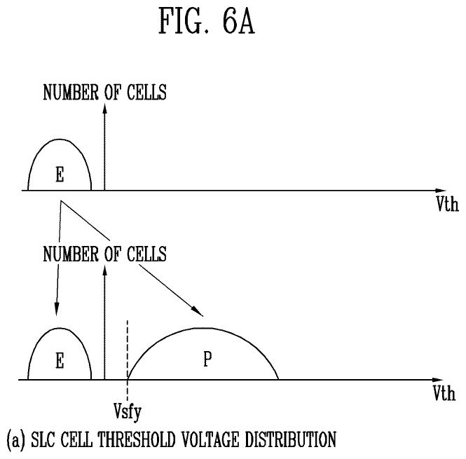

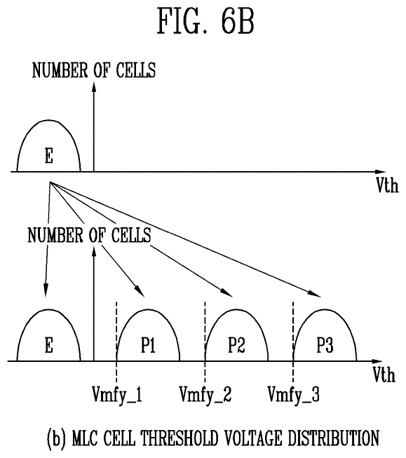

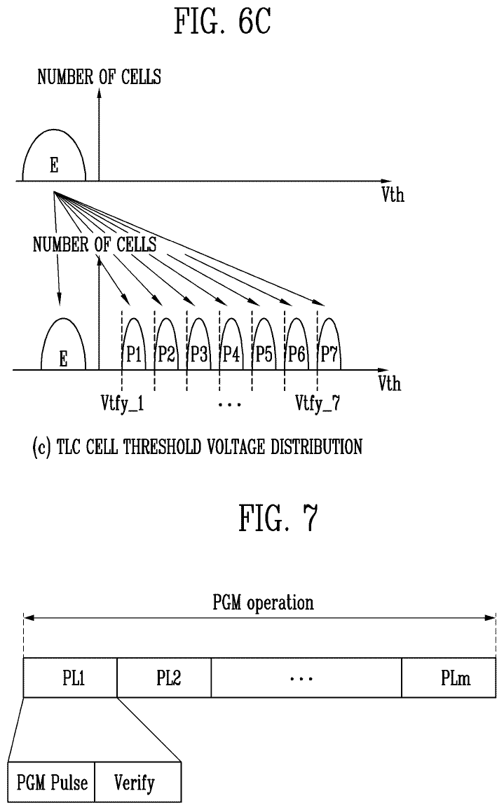

FIGS. 6A, 6B, and 6C are diagrams illustrating embodiments of program operations of a memory device.

FIGS. 6A, 6B, and 6C illustrate program operations of a single level cell (SLC) program method, a multi-level cell (MLC) program method, and a triple level cell (TLC) program method, respectively.

More specifically, FIG. 6A is a diagram illustrating a threshold voltage distribution of SLC memory cells storing one bit of data per cell during a program operation. FIG. 6B is a diagram illustrating a threshold voltage distribution of MLC memory cells storing two bits of data per memory cell during a program operation. FIG. 6C is a diagram illustrating a threshold voltage distribution of TLC memory cells storing three bits of data per memory cell during a program operation.

Referring to FIG. 6A, each of the SLC memory cells may have a target program state, which may be one of an erase state E and one program state P. The target program state may be determined based on data to be stored in each memory cell. The SLC memory cells may be in the erase state E before a program operation is performed. Subsequently, as the program operation proceeds, the SLC memory cells may reach the target program state. The program operation may be performed in units of pages, each including a plurality of memory cells coupled to a single word line. The memory cell array may include a plurality of pages, and among the plurality of pages, an address may determine which page is to be programmed. When the program operation for the corresponding page ends, the program operation for the next page may be performed. The program operation may include a program pulse apply operation and a program verify operation. During the program pulse apply operation, a program voltage may be applied to a selected word line which is coupled in common to memory cells included in the page on which the program operation is performed. During the program verify operation, a program result may be verified using a verify voltage. The memory cells having the program state P as the target program state may be memory cells to which the verify operation by a verify voltage Vsfy is passed. When the memory cells coupled to the selected word line all reach the target program state, the program operation of the selected word line may be considered to be terminated.

Referring to FIG. 6B, each of the MLC memory cells may have one of the erase state E and first to third program states P1 to P3 as a target program state. The target program state may be determined based on data to be stored in each memory cell. The MLC memory cells may be in the erase state E before a program operation is performed. Subsequently, as the program operation proceeds, the MLC memory cells may reach the target program state. The program operation may be performed in units of pages, each including a plurality of memory cells coupled to a single word line. The memory cell array may include a plurality of pages, and among the plurality of pages, an address may determine which page is to be programmed. When the program operation for the corresponding page ends, the program operation for the next page may be performed. The program operation may include a program pulse apply operation and a program verify operation. During the program pulse apply operation, a program voltage may be applied to a selected word line which is coupled in common to memory cells included in the page on which the program operation is performed. During the program verify operation, a program result may be verified using a verify voltage. The memory cells having the first program state P1 as the target program state may be memory cells to which a verify operation by a first multi-verify voltage Vmfy_1 has been passed. The memory cells having the second program state P2 as the target program state may be memory cells to which a verify operation by a second multi-verify voltage Vmfy_2 has been passed. The memory cells having the third program state P3 as the target program state may be memory cells to which the verify operation by a third multi-verify voltage Vmfy_3 has been passed. When the memory cells coupled to the selected word line all reach the target program state, the program operation of the selected word line may be considered to be terminated.

Referring to FIG. 6C, each of the TLC memory cells may have one of the erase state E and the first to seventh program states P1 to P7 as a target program state. A method of performing a program operation is similar to that in FIG. 6B as described above. However, since the TLC memory cells may store three bits of data, the number of threshold voltage distributions which need to be generated is larger than that of the program operation of the MLC memory cells. In other words, a total of four threshold voltage distributions are formed when the program operation for the MLC memory cells is terminated, but a total of eight threshold voltage distributions may be formed when the program operation for the TLC memory cells is terminated. For this purpose, a first verify voltage Vtfy1 to a seventh verify voltage Vtfy7 can be used. TLC memory cells may store more data than MLC memory cells.

FIG. 7 is a diagram illustrating a plurality of program loops included in a program operation of a memory device.

Referring to FIG. 7, a program operation may include a plurality of program loops. For example, the program operation may include a first program loop PL1 to an mth program loop PLm. A plurality of memory cells coupled to a selected word line and included in a selected page may be programmed to at least one program state through the program operation. An erase state and at least one program state may be distinguished based on threshold voltages of memory cells. For example, when the memory cells included in the selected page are programmed in a single-level cell (SLC) programming scheme, the memory cells may be divided into an erase state and one program state. When the memory cells included in the selected page are programmed with the Multi-Level Cell (MLC) programming scheme, the memory cells may be divided into an erase state and three program states. Also, when the memory cells included in the selected page are programmed with the Triple Level Cell (TLC) programming scheme, the memory cells may be divided into an erase state and seven program states.

Each program loop may include a program pulse apply operation PGM Pulse and a program verify operation Verify.

The program pulse apply operation PGM Pulse may be a section in which data is programmed into the memory cells included in the selected page. The program operation Verify may be a section in which the data programmed into the memory cells is verified.

When one program loop is performed, and a result of the program verify operation Verify is determined as a program pass, the program operation may be terminated.

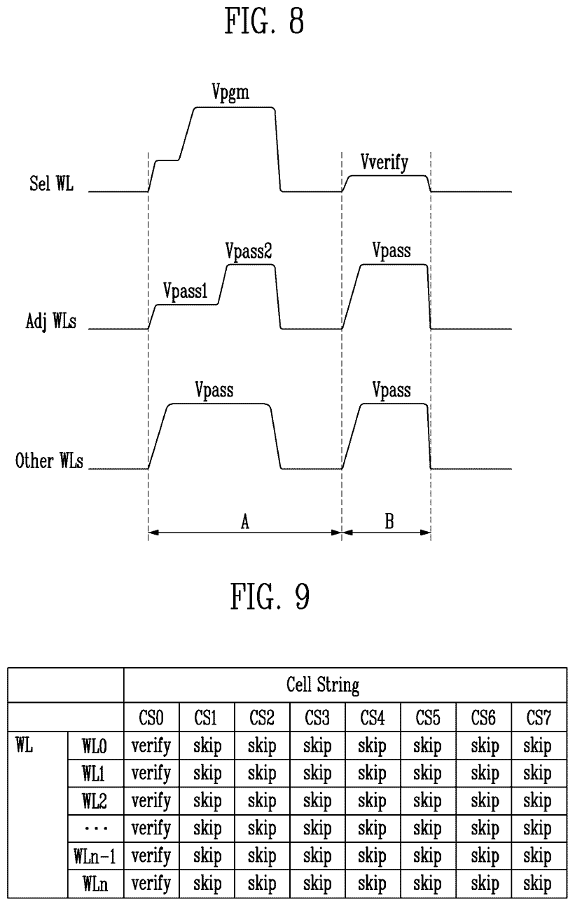

FIG. 8 is a diagram illustrating a program pulse apply operation and a program verify operation.

Referring to FIG. 8, in an execution section A of the program pulse apply operation, a program voltage Vpgm is applied to a selected word line Sel WL corresponding to a selected page. The program voltage Vpgm may be stepped up. For example, the program voltage Vpgm may increase to a level, maintained at the level for a duration of time, then increased, and then maintained at a level for another duration of time as shown in section A.

In the execution section A of the program pulse apply operation, first and second program pass voltages Vpass1 and Vpass2 may be applied sequentially to adjacent word lines Adj WLs which are physically close to the selected word line Sel WL. The second program pass voltage Vpass2 may have a higher potential than the first program pass voltage Vpass1.

In the execution section A of the program pulse apply operation, a program pass voltage Vpass may be applied to remaining word lines Other WLs except the selected word line Sel WL and the adjacent word lines Adj WLs. The program pass voltage Vpass may have the same potential as the second program pass voltage Vpass2.

After the execution section A of the program pulse apply operation is terminated, in an execution section B of the program verify operation, a verify voltage Vverify is applied to the selected word line Sel WL.

In the execution section B of the program verify operation, the program pass voltage Vpass may be applied to the adjacent word lines Adj WLs and the remaining word lines Other WLs.

FIG. 9 is a diagram illustrating a program operation according to an embodiment of the present disclosure.

Referring to FIGS. 2, 5, 6A, 7, 8, and 9, a program operation according to an embodiment of the present disclosure is described below.

During a program operation for a selected memory block (e.g., BLK1), the control logic 130 may control the peripheral circuit 120 to program the selected memory block BLK1 in a single level cell (SLC) programming scheme. In the single-level cell (SLC) programming scheme, fewer bits of data are stored in each of the memory cells compared to a multi-level cell (MLC) programming scheme or a triple-level cell (TLC) programming scheme, but the data may be more reliable compared to the multi-level cell (MLC) programming scheme or the triple-level cell (TLC) programming scheme since one memory cell is programmed in an erase state or a program state. Accordingly, in an embodiment, critical data or system data where reliability is important may be stored in the selected memory block BLK1 programmed by the single-level cell (SLC) programming scheme.

The program operation controller 131 of the control logic 130 may set detailed operations of the plurality of program loops PL1 to PLm included in the program operation when the selected memory block BLK1 is programmed in the single-level cell (SLC) programming scheme. For example, the program operation controller 131 may set the detailed operations such that the program pulse apply operation PGM Pulse and the program verify operation Verify may be performed for at least one selected cell string (e.g., CS0) of a plurality of cell strings (e.g., CS0 to CS7) included in the selected memory block BLK1, and the program pulse apply operation PGM Pulse may be performed for the remaining cell strings (CS1 to CS7) and the program verify operation Verify may be skipped.

The control logic 130 may control the peripheral circuit 120 to sequentially perform the plurality of program loops PL1 to PLm having detailed operations that are set by the program operation controller 131.

For example, the peripheral circuit 120 may perform the first program loop PL1 which includes the program pulse apply operation PGM Pulse and the program verify operation Verify.

In the execution section A of the program pulse apply operation, the voltage generator 122 generates and outputs the program voltage Vpgm, the first and second program pass voltages Vpass1 and Vpass2, and the program pass voltage Vpass. In the execution section A of the program pulse apply operation, the row decoder 121 may apply the program voltage Vpgm to the selected word line Sel WL, and apply the first and second program pass voltages Vpass1 and Vpass2 to the adjacent word lines Adj WLs. The row decoder 121 may apply the program pass voltages Vpass to the remaining word lines Other WLs.

In the execution section B of the program verify operation, the voltage generator 122 may generate the verify voltage Vverify and the program pass voltage Vpass. In the execution section B of the program verify operation, the row decoder 121 may apply the verify voltage Vverify to the selected word line Sel WL, and may apply the program pass voltage Vpass to the adjacent word lines Adj WLs and the remaining word lines Other WLs.

In the execution section B of the program verify operation, a page buffer (e.g., PB1) corresponding to at least one selected cell string (e.g., CS0) among the first to nth page buffers PB1 to PBn included in the page buffer group 123 performs a program verify operation, and the remaining page buffers (e.g., PB2 to PBn) do not perform the program verify operation. For example, the page buffer PB1 corresponding to at least one selected cell string (e.g., CS0) may sense a current amount or a voltage through a bit line (e.g., BL1) coupled to at least one selected cell string (e.g., CS0) and may determine a program pass or a program fail based on the sensed current amount or voltage.

When a result of the program verify operation for at least one selected cell string CS0 as described above is determined to be a program pass, the program operation may be completed. On the other hand, when the result of the program verify operation for at least one selected cell string CS0 as described above is determined to be a program fail, the next program loop (e.g., PL2) may be performed.

Upon completion of the program operation for the selected word line, the next word line may be selected and the program operation may be performed in a manner similar to the program operation described above.

According to an embodiment of the present disclosure described above, when a selected memory block is programmed by a single-level cell programming scheme, a program verify operation is performed for at least one cell string of a plurality of cell strings included in the selected memory block, and a program verify operation is skipped for the remaining cell strings, so that, in an embodiment, a speed of the program operation may be improved, and the current consumption of the program operation may be reduced.

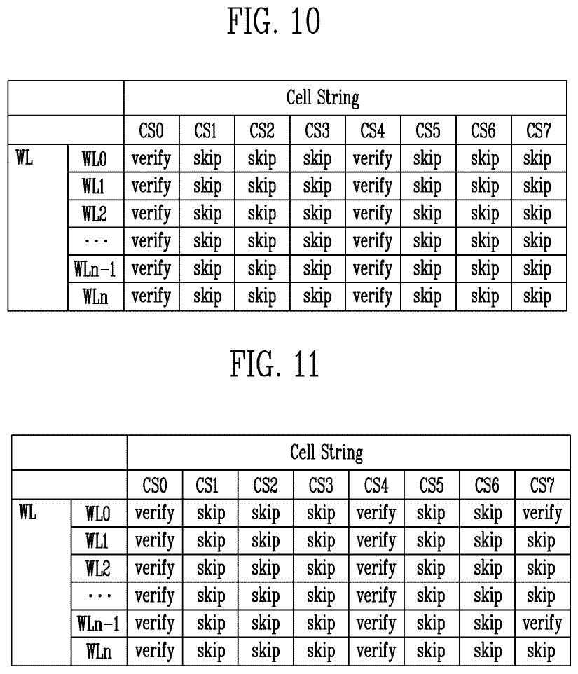

FIG. 10 is a diagram illustrating a program operation according to an embodiment of the present disclosure.

Referring to FIGS. 2, 5, 6A, 7, 8, and 10, a program operation according to an embodiment of the present disclosure is described as follows.

During a program operation for a selected memory block (e.g., BLK1), the control logic 130 may control the peripheral circuit 120 to program the selected memory block BLK1 in a single level cell (SLC) programming scheme.

The program operation controller 131 of the control logic 130 may set detailed operations of the plurality of program loops PL1 to PLm included in the program operation when the selected memory block BLK1 is programmed in the single-level cell (SLC) programming scheme. For example, the program operation controller 131 may set the detailed operations such that the program pulse apply operation PGM Pulse and the program verify operation Verify may be performed for selected cell strings (e.g., CS0 and CS4) of a plurality of cell strings (e.g., CS0 to CS7) included in the selected memory block BLK1, and the program pulse apply operation PGM Pulse may be performed for the remaining cell strings (CS1 to CS3 and CS5 to CS7) and the program verify operation Verify may be skipped. The selected cell strings (e.g., CS0 and CS4) may be weak cell strings. The weak cell strings may refer to cell strings in which program disturbance occurs relatively severely during a program operation. The weak cell strings may be located in an edge region among the plurality of cell strings included in the selected memory block.

The control logic 130 may control the peripheral circuit 120 to sequentially perform the plurality of program loops PL1 to PLm having detailed operations that are set by the program operation controller 131.

For example, the peripheral circuit 120 may perform the first program loop PL1 which includes the program pulse apply operation PGM Pulse and the program verify operation Verify.

In the execution section A of the program pulse apply operation, the voltage generator 122 generates and outputs the program voltage Vpgm, the first and second program pass voltages Vpass1 and Vpass2, and the program pass voltage Vpass. In the execution section A of the program pulse apply operation, the row decoder 121 may apply the program voltage Vpgm to the selected word line Sel WL, and apply the first and second program pass voltages Vpass1 and Vpass2 to the adjacent word lines Adj WLs. The row decoder 121 may apply the program pass voltages Vpass to the remaining word lines Other WLs.

In the execution section B of the program verify operation, the voltage generator 122 may generate the verify voltage Vverify and the program pass voltage Vpass. In the execution section B of the program verify operation, the row decoder 121 may apply the verify voltage Vverify to the selected word line Sel WL, and may apply the program pass voltage Vpass to the adjacent word lines Adj WLs and the remaining word lines Other WLs.

In the execution section B of the program verify operation, page buffers corresponding to the selected cell strings (e.g., CS0 and CS4) among the first to nth page buffers PB1 to PBn included in the page buffer group 123 perform a program verify operation, and the remaining page buffers do not perform the program verify operation. For example, each of the page buffers corresponding to the selected cell strings (e.g., CS0 and CS4) may sense a current amount or a voltage through bit lines coupled to the selected cell strings (e.g., CS0 and CS4) and may determine a program pass or a program fail based on the sensed current amount or voltage.

When a result of the program verify operation for the selected cell strings (e.g., CS0 and CS4) as described above is determined to be a program pass, the program operation may be completed. On the other hand, when the result of the program verify operation for the selected cell strings (e.g., CS0 and CS4) as described above is determined to be a program fail, the next program loop (e.g., PL2) may be performed.

Upon completion of the program operation for the selected word line, the next word line may be selected and the program operation may be performed in a manner similar to the program operation described above.

According to an embodiment of the present disclosure described above, when a selected memory block is programmed by a single-level cell programming scheme, a program verify operation is performed for only a weak cell string of a plurality of cell strings included in the selected memory block, and a program verify operation is skipped for the remaining cell strings, so that a speed of the program operation may be improved, and the current consumption of the program operation may be reduced.

FIG. 11 is a diagram illustrating a program operation according to an embodiment of the present disclosure.

Referring to FIGS. 2, 5, 6A, 7, 8, and 11, a program operation according to an embodiment of the present disclosure will be described below.

During a program operation for a selected memory block (e.g., BLK1), the control logic 130 may control the peripheral circuit 120 to program the selected memory block BLK1 in the single level cell (SLC) programming scheme.

During the program operation for the selected memory block (e.g., BLK1), a plurality of pages included in the selected memory block (e.g., BLK1) may be sequentially selected to perform the program operation. For example, the program operation for may be performed on a page corresponding to a word line WL0, and when the program operation for the page corresponding to the word line WL0 is completed, the program operation may be performed on a page corresponding to a next word line WL1.

The program operation controller 131 of the control logic 130 may set detailed operations of the plurality of program loops PL1 to PLm included in the program operation when the selected memory block BLK1 is programmed in the single-level cell (SLC) programming scheme. For example, the program operation controller 131 may set the detailed operations such that the program pulse apply operation PGM Pulse and the program verify operation Verify may be performed for selected cell strings (e.g., CS0 and CS4) of the plurality of cell strings (e.g., CS0 to CS7) included in the selected memory block BLK1, and the program pulse apply operation PGM Pulse may be performed for the remaining cell strings (CS1 to CS3 and CS5 to CS7), and the program verify operation Verify may be skipped. Further, the program operation controller 131 may set the detailed operations such that the program pulse apply operation PGM Pulse and the program verify operation Verify may be performed for some memory cells. These memory cells may be memory cells where program disturbance is relatively large. For example, the program operation controller 131 may set such that the program pulse apply operation PGM Pulse and the program verify operation Verify may be performed for memory cells coupled to some word lines (WL0 and WLn-1) among memory cells included in some cell strings (e.g., CS7) of the remaining cell strings (e.g., CS1 to CS3 and CS5 to CS7). The selected cell strings (e.g., CS0 and CS4) may be weak cell strings. The weak cell strings may be cell strings in which a relatively large program disturbance occurs during the program operation. The weak cell strings may be located in an edge region among the plurality of cell strings included in the selected memory block.

The control logic 130 may control the peripheral circuit 120 to sequentially perform the plurality of program loops PL1 to PLm, the detailed operations of which are set by the program operation control unit 131, during the program operation for the selected word line (e.g., WL0).

For example, the peripheral circuit 120 may perform the first program loop PL1 including the program pulse apply operation PGM Pulse and the program verify operation Verify.

In the execution section A of the program pulse apply operation, the voltage generator 122 generates and outputs the program voltage Vpgm, the first and second program pass voltages Vpass1 and Vpass2, and the program pass voltage Vpass. In the execution section A of the program pulse apply operation, the row decoder 121 may apply the program voltage Vpgm to the selected word line Sel WL, and apply the first and second program pass voltages Vpass1 and Vpass2 to the adjacent word lines Adj WLs. The row decoder 121 may apply the program pass voltages Vpass to the remaining word lines other WLs.

In the execution section B of the program verify operation, the voltage generator 122 may generate the verify voltage Vverify and the program pass voltage Vpass. In the execution section B of the program verify operation, the row decoder 121 may apply the verify voltage Vverify to the selected word line Sel WL, and may apply the program pass voltage Vpass to the adjacent word lines Adj WLs and the remaining word lines Other WLs.

In the execution section B of the program verify operation, page buffers corresponding to the selected cell strings (e.g., CS0 and CS4) among the first to nth page buffers PB1 to PBn included in the page buffer group 123 and a page buffer corresponding to a cell string (e.g., CS7) including a weak memory cell perform a program verify operation, and the remaining page buffers do not perform the program verify operation. For example, each of the page buffers corresponding to the selected cell strings (e.g., CS0 and CS4) and the page buffer corresponding to the cell string (e.g., CS7) including the weak memory cell may sense a current amount or a voltage through bit lines coupled to the cell strings (e.g., CS0, CS4, and CS7), and may determine a program pass or a program fail of each of the cell strings (e.g., CS0, CS4, and CS7) based on the sensed current amount or voltage.

As a result of the program verify operation for the cell strings (e.g., CS0, CS4, and CS7) as described above, when the cell strings (e.g., CS0, CS4, and CS7) are all determined to be a program pass, the program operation may be completed. However, when at least one of the cell strings is determined to be a program fail as the result of the program verify operation for the cell strings (e.g., CS0, CS4, and CS7) described above, the next program loop (e.g., PL2) may be performed.

When the program operation for the selected word line WL0 is completed, the next word line WL1 may be selected to perform the program operation as described above.

According to an embodiment of the present disclosure as described above, when a selected memory block is programmed by a single-level cell programming scheme, a program verify operation is performed for only a weak cell string of a plurality of cell strings included in the selected memory block, and a program verify operation is skipped for the remaining cell strings, so that a speed of the program operation may be improved, and the current consumption of the program operation may be reduced. Further, when some of the remaining cell strings include weak memory cells, a program verify operation may be set to be selectively performed for the weak memory cells during a program operation of a word line corresponding to the weak memory cells.

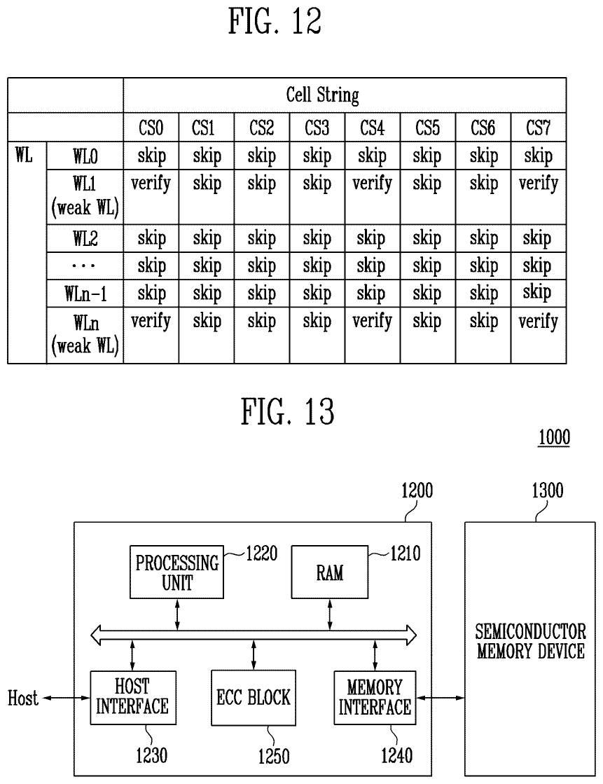

FIG. 12 is a diagram illustrating a program operation according to an embodiment of the present disclosure.

Referring to FIGS. 2, 5, 6A, 7, 8, and 12, a program operation according to an embodiment of the present disclosure is described below.

During a program operation for a selected memory block (e.g., BLK1), the control logic 130 may control the peripheral circuit 120 to program the selected memory block BLK1 in a single level cell (SLC) programming scheme.

During the program operation for the selected memory block (e.g., BLK1), a plurality of pages included in the selected memory block (e.g., BLK1) may be sequentially selected to perform the program operation. For example, when the program operation is performed on a page corresponding to the word line WL0, and the program operation on the page corresponding to the word line WL0 is completed, the program operation may be performed on a page corresponding to the next word line WL1.

The program operation controller 131 of the control logic 130 may set detailed operations of the plurality of program loops PL1 to PLm included in the program operation when the selected memory block BLK1 is programmed in the single-level cell (SLC) programming scheme. For example, during a program operation for pages coupled to weak word lines (e.g., WL1 and WLn) among the pages included in the selected memory block BLK1, the program operation controller 131 may set the detailed operations such that the program pulse apply operation PGM Pulse and the program verify operation Verify may be performed on selected cell strings (e.g., CS0, CS4, and CS7) among the plurality of cell strings (e.g., CS0 to CS7), and the program pulse apply operation PGM Pulse may be performed for the remaining cell strings (CS1 to CS3, CS5, and CS6), and the program verify operation Verify may be skipped. The weak word lines may correspond to pages where a relatively large program disturbance occurs during the program operation. The selected cell strings (e.g., CS0, CS4, and CS7) may be weak cell strings. The weak cell strings may experience relatively large program disturbances during the program operation.

The control logic 130 may control the peripheral circuit 120 to sequentially perform the plurality of program loops PL1 to PLm having detailed operations that are set by the program operation controller 131 during the program operation for the selected word line (e.g., WL1).

For example, the peripheral circuit 120 may perform the first program loop PL1 which includes the program pulse apply operation PGM Pulse and the program verify operation Verify.

In the execution section A of the program pulse apply operation, the voltage generator 122 generates and outputs the program voltage Vpgm, the first and second program pass voltages Vpass1 and Vpass2, and the program pass voltage Vpass. In the execution section A of the program pulse apply operation, the row decoder 121 may apply the program voltage Vpgm to the selected word line Sel WL, and apply the first and second program pass voltages Vpass1 and Vpass2 to the adjacent word lines Adj WLs. The row decoder 121 may apply the program pass voltages Vpass to the remaining word lines Other WLs.

In the execution section B of the program verify operation, the voltage generator 122 may generate the verify voltage Vverify and the program pass voltage Vpass. In the execution section B of the program verify operation, the row decoder 121 may apply the verify voltage Vverify to the selected word line Sel WL, and may apply the program pass voltage Vpass to the adjacent word lines Adj WLs and the remaining word lines Other WLs.

In the execution section B of the program verify operation, page buffers corresponding to the selected cell strings (e.g., CS0, CS4, and CS7) among the first to nth page buffers PB1 to PBn included in the page buffer group 123 perform the program verify operation, and the remaining page buffers do not perform the program verify operation. For example, each of the page buffers corresponding to the selected cell strings (e.g., CS0, CS4, and CS7) may sense a current amount or a voltage through bit lines coupled to the cell strings (e.g., CS0, CS4, and CS7), and may determine a program pass or a program fail of each of the cell strings (e.g., CS0, CS4, and CS7) based on the sensed current amount or voltage.

As a result of the program verify operation for the cell strings (e.g., CS0, CS4, and CS7) as described above, when the cell strings (e.g., CS0, CS4, and CS7) are all determined to be a program pass, the program operation may be completed. When at least one of the cell strings is determined to be a program fail as a result of the program verify operation for the above-described cell strings (e.g., CS0, CS4, and CS7), the next program loop (e.g., PL2) may be performed.

When the program operation for the selected word line WL0 is completed, the next word line WL2 may be selected to perform the above-described program operation.

According to an embodiment of the present disclosure described above, when a selected memory block is programmed by a single-level cell programming scheme, a program verify operation is performed for only a weak cell string of a plurality of cell strings, and a program verify operation is skipped for the remaining cell strings during a program operation of a page corresponding to the weak word line among a plurality of pages included in the selected memory block, so that a speed of the program operation may be improved, and the current consumption of the program operation may be reduced.

In an embodiment, a program verify operation may be selectively performed for cell strings which are different from each other based on a selected word line during a program operation.

For example, when the selected word line is the word line WL0 in the program operation, a program verify operation may be selectively performed only for memory cells included in the cell string CS0 among memory cells coupled to the selected word line WL0, and a program verify operation may be skipped for memory cells included in the remaining cell strings CS1 to CS7. Further, when the selected word line is the word line WL1, the program verify operation may be selectively performed only for the memory cells included in the cell string CS1 among the memory cells coupled to the selected word line WL1, and the program verify operation may be skipped for the memory cells included in the remaining cell strings CS0 and CS2 to CS7. Also, when the selected word line is the word line WL2, the program verify operation may be selectively performed only for the memory cells included in the cell string CS2 among the memory cells coupled to the selected word line WL2, and the program verify operation may be skipped for the memory cells included in the remaining cell strings CS0, CS1, and CS3 to CS7. In this manner, based on the selected word line in the program verify operation, the program verify operation may be selectively performed for the memory cells corresponding to at least one cell string of the plurality of cell strings, and the program verify operation may be skipped for the memory cells corresponding to the remaining cell strings.

FIG. 13 is a block diagram illustrating a storage device including a memory device according to an embodiment of the present disclosure.

Referring to FIG. 13, the storage device 1000 may include a semiconductor memory device 1300 and a controller 1200.

The semiconductor memory device 1300 may be configured and operated in substantially the same manner as the memory device 100 as described above with reference to FIG. 1. Hereinafter, overlapping desertions will be omitted.

The controller 1200 may be coupled to a host and the semiconductor memory device 1300. The controller 1200 may access the semiconductor memory device 1300 at the request of the host. For example, the controller 1200 may control read, program, erase, and background operations of the semiconductor memory device 1300. The controller 1200 may provide an interface between the semiconductor memory device 1300 and the host. The controller 1200 may drive firmware for controlling the semiconductor memory device 1300.

The controller 1200 may include a random access memory (RAM) 1210, a processing unit 1220, a host interface 1230, a memory interface 1240 and an error correction code (ECC) block 1250.

The RAM 1210 may serve as an operation memory of the processing unit 1220, a cache memory between the semiconductor memory device 1300 and the host, and a buffer memory between the semiconductor memory device 1300 and the host.

The processing unit 1220 may control operations of the controller 1200. The processing unit 1220 may control a read operation, a program operation, an erase operation, and a background operation of the semiconductor memory device 1000. The processing unit 1220 may operate firmware to control the semiconductor memory device 1000. According to an embodiment, the processing unit 1220 may function as a flash translation layer FTL. The processing unit 1220 may translate a logical block address LBA provided by the host into a physical block address PBA through the flash translation layer FTL. The flash translation layer FTL may receive the logical block address LBA by using a mapping table and translate the logical block address LBA into the physical block address PBA. There may be various address mapping methods for the flash translation layer according to a mapping unit. Examples of these address mapping methods may include a page mapping method, a block mapping method, and a hybrid mapping method.

The processing unit 1220 may randomize data received from the host. For example, the processing unit 1220 may randomize the data received from the host by using a randomizing seed. The randomized data may be provided to the semiconductor memory device 1300, so that the memory cell array may be programmed with the randomized data.

The processing unit 1220 may derandomize the data from the semiconductor memory device 1300 during a read operation. For example, the processing unit 1220 may derandomize the data received from the semiconductor memory device 1000 by using a derandomizing seed. The derandomized data may be output to the host.

According to an embodiment, the processing unit 1220 may perform randomizing and derandomizing operations by driving software or firmware.

The host interface 1230 may include a protocol for data exchange between the host and the controller 1200. According to an embodiment, the controller 1200 may communicate with the host using at least one of a variety of interface protocols, such as a universal serial bus (USB) protocol, a multimedia card (MMC) protocol, a peripheral component interconnection (PCI) protocol, a PCI-Express (PCI-E) protocol, an advanced technology attachment (ATA) protocol, a Serial-ATA protocol, a Parallel-ATA protocol, a small computer small interface (SCSI) protocol, an enhanced small disk interface (ESDI) protocol, an integrated drive electronics (IDE) protocol, and a private protocol.

The memory interface 1240 may interface with the semiconductor memory device 1300. For example, the memory interface 1240 may include a NAND flash interface or a NOR flash interface.

The ECC block 1250 may detect and correct an error in data received from the semiconductor memory device 1300 by using an error correction code (ECC). In addition, the ECC block 1250 may correct an error in the read page data by using the error correction code (ECC). The ECC block 1250 may correct an error by using coded modulation, such as low density parity check (LDPC) code, Bose-Chaudhuri-Hocquenghem code (BCH) code, turbo code, Reed-Solomon code, convolution code, recursive systematic code (RSC), trellis-coded modulation (TCM), block coded modulation (BCM), and hamming code.

The controller 1200 and the semiconductor memory device 1300 may be integrated in one semiconductor device. According to an embodiment, the controller 1200 and the semiconductor memory device 1300 may be integrated in a single semiconductor device to form a memory card such as a PC card (personal computer memory card international association (PCMCIA)), a compact flash card (CF), a smart media card (SMC), a memory stick, a multimedia card (MMC, RS-MMC or MMCmicro), an SD card (SD, miniSD, micro SD or SDHC), a universal flash storage device (UFS), etc.

The controller 1200 and the semiconductor memory device 1300 may be integrated in a single semiconductor device to form a solid state drive (SSD). The SSD may include a storage device for storing data in a semiconductor memory device. In an embodiment, when the storage device 1000 is used as an SSD, operational rates of the host coupled to the storage device 1000 may be significantly improved.

In another example, the storage device 1000 may be provide as one of various components in various electronic devices such as a computer, an ultra mobile PC (UMPC), a workstation, a net-book, a personal digital assistant (PDA), a portable computer, a web table, a wireless phone, a mobile phone, a smart phone, an e-book, a portable multimedia player (PMP), a portable game machine, a navigation device, a black box, a digital camera, a three-dimensional television, a digital audio recorder, a digital audio player, a digital picture recorder, a digital picture player, a digital video recorder, a digital video player, a device for transmitting/receiving information in wireless environments, one of various electronic devices for home networks, one of various devices for computer networks, one of various electronic devices for telematics networks, an RFID device, one of various components for computing systems, etc.

According to an embodiment, the semiconductor memory device 1300 or the storage device 1000 may be packaged in various forms. For example, the semiconductor memory device 1300 or the storage device 1000 may be packaged by various methods such as Package on Package (PoP), Ball grid arrays (BGAs), Chip scale packages (CSPs), Plastic Leaded Chip Carrier (PLCC), Plastic Dual In Line Package (PDIP), Die in Waffle Pack, Die in Wafer Form, Chip On Board (COB), Ceramic Dual In Line Package (CERDIP), Plastic Metric Quad Flat Pack (MQFP), Thin Quad Flat Pack (TQFP), Small Outline Integrated Circuit (SOIC), Shrink Small Outline Package (SSOP), Thin Small Outline Package (TSOP), Thin Quad Flatpack (TQFP), System In Package (SIP), Multi-Chip Package (MCP), Wafer-level Fabricated Package(WFP), Wafer-Level Processed Stack Package (WSP), etc.

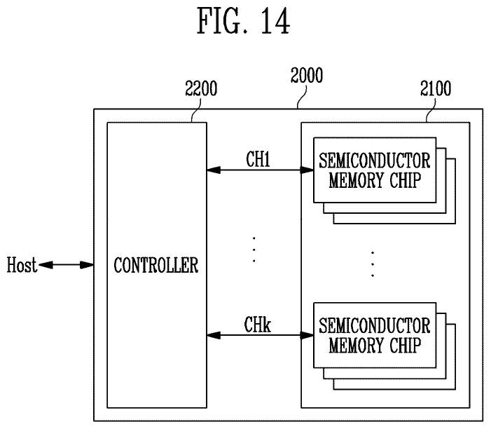

FIG. 14 is a block diagram illustrating an application example of the storage device shown in FIG. 13.

Referring to FIG. 14, a storage device 2000 may include a semiconductor memory device 2100 and a controller 2200. The semiconductor memory device 2100 may include semiconductor memory chips. The semiconductor memory chips may be divided into groups.

FIG. 14 illustrates a plurality of groups communicating with the controller 2200 through first to k-th channels CH1 to CHk. Each of the semiconductor memory chips may be configured and operated in substantially the same manner as the semiconductor memory device 100 described above with reference to FIG. 1.

Each group may communicate with the controller 2200 through a single common channel. The controller 2200 may be configured in substantially the same manner as the controller 1200 described with reference to FIG. 13, and may control the plurality of memory chips of the semiconductor memory device 2100 through the plurality of channels CH1 to CHk.

As shown in FIG. 14, a plurality of semiconductor memory chips may be coupled to a single channel. However, the storage device 2000 may be modified so that a single semiconductor memory chip may be coupled to a single channel.

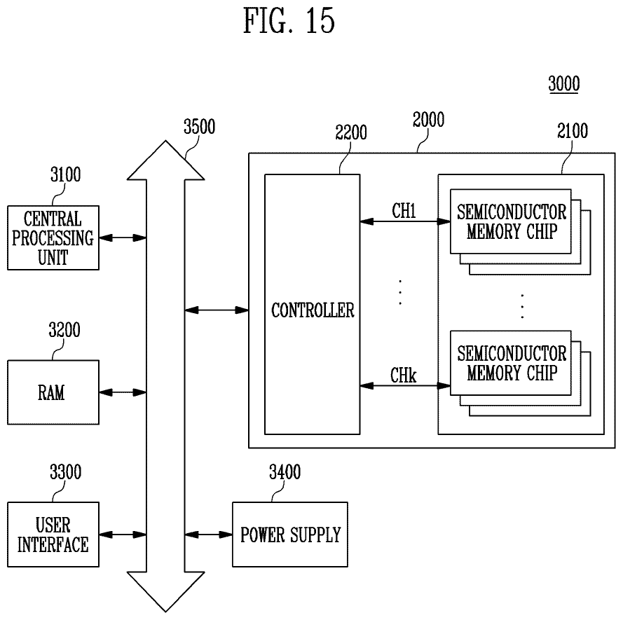

FIG. 15 is a block diagram illustrating a computing system 3000 including the storage device 2000 described above with reference to FIG. 14.

Referring to FIG. 15, the computing system 3000 may include a central processing unit 3100, a random access memory (RAM) 3200, a user interface 3300, a power supply 3400, a system bus 3500, and the storage device 2000.

The storage device 2000 may be electrically connected to the central processing unit 3100, the RAM 3200, the user interface 3300, and the power supply 3400 through the system bus 3500. Data provided through the user interface 3300 or processed by the central processing unit 3100 may be stored in the storage device 2000.

As shown in FIG. 15, the semiconductor memory device 2100 may be coupled to the system bus 3500 through the controller 2200. However, the semiconductor memory device 2100 may be directly coupled to the system bus 3500. The central processing unit 3100 and the RAM 3200 may perform functions of the controller 2200.

As shown in FIG. 15, the storage device 2000 shown in FIG. 14 may be provided as the memory system 3000. However, the storage device 2000 may be replaced by the storage device 1000 shown in FIG. 13. According to an embodiment, the computing system 3000 may include both of the memory systems 1000 and 2000 described above with reference to FIGS. 13 and 14.

According to an embodiment of the present disclosure, a memory device having improved program performance and an operating method thereof are provided.

It will be apparent to those skilled in the art which various modifications can be made to the above-described embodiments of the present disclosure without departing from the spirit or scope of the disclosure. Thus, it is intended that the embodiments cover all such modifications provided they come in the scope of the appended claims and their equivalents.

What is claimed is:

1. A memory device, comprising:
a memory block including a plurality of cell strings;
a peripheral circuit configured to perform a program operation on the memory block; and
control logic configured to control the peripheral circuit to perform the program operation,
wherein the control logic sets a detailed operation of each of a plurality of program loops included in the program operation such that a program verify operation of each of the plurality of program loops is performed only for at least one selected cell string of the plurality of cell strings.

2. The memory device of claim 1, wherein the control logic comprises a program operation controller, and the program operation controller sets the program verify operation to be omitted for remaining cell strings of the plurality of cell strings except for the at least one selected cell string.

3. The memory device of claim 1, wherein the peripheral circuit performs the plurality of program loops sequentially, and terminates the program operation when a program verify result of the at least one selected cell string is determined as a pass during the program verify operation of a program loop being currently performed.

4. The memory device of claim 1, wherein the peripheral circuit performs the plurality of program loops sequentially, and performs a subsequent program loop when a program verify result of the at least one selected cell string is determined as a fail during the program verify operation of a currently performed program loop.

5. The memory device of claim 1, wherein a program disturbance occurs more in the at least one selected cell string than remaining cell strings of the plurality of cell strings except for the at least one selected cell string.

6. The memory device of claim 1, wherein the at least one selected cell string is a cell string arranged in an edge region among the plurality of cell strings.

7. The memory device of claim 1, wherein the peripheral circuit programs memory cells included in the memory block in a single-level cell programming scheme.

8. The memory device of claim 1, wherein the program verify operation is set to be performed for a portion of the plurality of cell strings and the program verify operation is set to be omitted for other cell strings, based on a selected word line for the program operation among a plurality of word lines coupled to the memory block.

9. A memory device, comprising:
a memory block including a plurality of cell strings;
a peripheral circuit configured to sequentially select a plurality of pages corresponding to a plurality of word lines coupled to the memory block, and perform a program operation on each of the plurality of pages; and
control logic configured to control the peripheral circuit to perform the program operation,
wherein the control logic sets a detailed operation for each of a plurality of program loops included in the program operation such that the plurality of program loops include a program verify operation in the program operation for at least one page of the plurality of pages, and the plurality of program loops omit the program verify operation in the program operation for remaining pages of the plurality of pages except for the at least one page.

10. The memory device of claim 9, wherein the control logic sets the plurality of program loops to perform the program verify operation only for a portion of memory cells included in at least one selected cell string of the plurality of cell strings during the program operation for the at least one page.

11. The memory device of claim 10, wherein the peripheral circuit completes the program operation for the at least one page and starts the program operation for a subsequent page when a program verify result of the at least one selected cell string is determined as a pass during the program verify operation of a currently performed program loop in the program operation for the at least one page.

12. The memory device of claim 10, wherein the peripheral circuit performs a subsequent program loop when a program verify result of the at least one selected cell string is determined as a fail during the program verify operation of a currently performed program loop in the program operation for the at least one page.

13. The memory device of claim 9, wherein the control logic comprises a program operation controller, and the program operation controller sets the plurality of program loops corresponding to each of the plurality of pages to perform or omit the program verify operation.

14. The memory device of claim 9, wherein a program disturbance occurs more in the at least one page than the remaining pages of the plurality of pages.

15. The memory device of claim 10, wherein a program disturbance occurs more in the at least one selected cell string than remaining cell strings of the plurality of cell strings except for the at least one selected cell string.

16. The memory device of claim 9, wherein the peripheral circuit programs memory cells included in the memory block in a single level cell programming scheme.

17. A method of operating a memory device, the method comprising:
performing a program pulse apply operation by applying a program voltage to a selected word line from a plurality of word lines coupled to a memory block, the memory block including a plurality of cell strings;
performing a program verify operation for a memory cell included in at least one cell string of the plurality of cell strings by sensing a current or a voltage through a bit line coupled to the at least one cell string, and omitting the program verify operation for remaining cell strings of the plurality of cell strings except for the at least one cell string; and
performing a subsequent program operation by performing a subsequent program loop or selecting a subsequent word line from the plurality of word lines, based on a result of the program verify operation for the memory cell included in the at least one cell string.

18. The method of claim 17, wherein memory cells coupled to the selected word line are programmed by a single-level cell programming scheme.

19. The method of claim 17, wherein a program disturbance occurs more in the at least one cell string than the remaining cell strings of the plurality of cell strings except for the at least one cell string.

20. The method of claim 17, wherein the omitting of the program verify operation comprises selecting the at least one cell string for which the program verify operation is performed among the plurality of cell strings, based on the selected word line of the plurality of word lines.
